(19) United States
(12) Patent Application Publication
(10) Pub. No.: US 2009/0072717 A1
(43) Pub. Date: Mar. 19, 2009

(54) Highly efficient polymer light-emitting diodes

(75) Inventors: Yang Yang, Los Angles, CA (US); Jinsong Huang, Andover, MA (US); Qianfei Xu, Mountain View, CA (US)

Correspondence Address: VENABLE LLP, P.O. BOX 34385, WASHINGTON, DC, 20043-9998, US

(73) Assignee: The Regents of the University of California, Oakland, CA (US)

(21) Appl. No.: 11/918,893

(22) PCT Filed: Apr. 21, 2006
(86) PCT No.: PCT/US2006/015048

§ 371 Date: Oct. 19, 2007

Related U.S. Application Data
(60) Provisional application No. 60/673,428, filed on Apr. 21, 2005.

(51) Int. Cl. H01J 1/63; B05D 5/12

(52) U.S. Cl. 313/504; 427/66

(57) ABSTRACT

An electro-optic device (100) has a first electrode (102), a second electrode (104), and an active polymer layer (106) disposed between the first and second electrodes. The active polymer layer is a blend of a high band gap material with a low band gap material. An electro-optic device has an anode, cathode spaced apart from the anode, and an active polymer layer (106) disposed between the cathode and anode. The cathode is constructed to provide both electron injection and hole blocking. A method of manufacturing an electrode-optic device include providing a substrate, forming a layer of Cs₂CO₃ (112) on the active polymer layer, and depositing a layer of metal (114) onto the layer of Cs₂CO₃ (112). The layer of Cs₂CO₃ (112) on the active polymer layer provides electron injection and hole blocking for the electro-opti device (100).

### CROSS-REFERENCE OF RELATED APPLICATION

This application claims priority to U.S. Provisional Application No. 60/673,428 filed Apr. 21, 2005, the entire contents of which are hereby incorporated by reference.

The U.S. Government has a paid-up license in this invention and the right in limited circumstances to require the patent owner to license others on reasonable terms as provided for by the terms of NSF Grant No. 0404029.

### BACKGROUND

1. Field of Invention

This application relates to highly efficient electro-optic devices and methods of manufacture, and more particularly to highly efficient polymer light-emitting diodes and methods of manufacture.

2. Discussion of Related Art

The contents of all references referred to herein, including articles, published patent applications and patents are hereby incorporated by reference.

The external electroluminescence quantum efficiency (QE_{EL}) of polymer light-emitting diodes (PLEDs) can be affected by the following four factors: (a) charge balance, (b) the efficiency of producing singlet excitons, (c) photoluminescence quantum efficiency (PL_{QE}), and (d) output coupling effects. (See Wolfgang Brutting, Stefan Berleb & Anton G. Muckl, Organic Electronics 2. 2002, 1.) The QE_{PL} can approach unity and the efficiency for the production of singlet excitons can be high in long-chain polymers. (See J. S. Wilson, A. S. Dhoot, A. J. A. B. Seeley, M. S. Khan, A. Kohler & R. H. Friend, Nature (London). 2001 413, 828; and M. Wohlgenannt, X. M. Jiang, Z. V. Vardeny & R. A. J. Janssen, Phys. Rev. Lett. 2002, 88, 197401.) Therefore, the main dominating factor for achieving high efficiency of a given polymer is the balance and confinement of electrons and holes. Unfortunately, most conjugated polymers have unbalanced charge transport properties as the mobility of holes is much greater than that of electrons. Generally, the balance of electrons and holes in PLEDs is attained by modifying the charge injection contact. For example, LiF is used as the cathode contact for efficient electron injection (L. S. Hung, C. W. Tang, and M. G. Mason, Appl. Phys. Lett. 1997, 70, 152). In addition to balanced charge injection; charge confinement is another dominating factor. In the past, charge confinement has been accomplished by introducing a charge blocking layer between an electron transport layer (ETL) and a hole transport layer (HTL). From a device fabrication point of view, it would be easier if a charge injection layer for one type of charge also serves as a charge blocking layer for another type of charge. Therefore, there remains a need for improved electro-optic devices such as polymer light-emitting diodes.

### SUMMARY

Further objectives and advantages will become apparent from a consideration of the description, drawings, and examples.

An electro-optic device according to an embodiment of the current invention has a first electrode, a second electrode spaced apart from the first electrode, and an active polymer layer disposed between the first electrode and the second electrode. The active polymer layer is a blend of a high band gap material with a low band gap material.

An electro-optic device according to an embodiment of the current invention has an anode, a cathode spaced apart from the anode, and an active polymer layer disposed between the cathode and the anode. The cathode is constructed to provide both electron injection and hole blocking.

A method of manufacturing an electro-optic device according to an embodiment of this invention includes providing a substrate, forming an active polymer layer on the substrate, forming a layer of Cs₂CO₃ on the active polymer layer, and depositing a layer of metal onto the layer of Cs₂CO₃. The layer of Cs₂CO₃ on the active polymer layer provides electron injection and hole blocking for the electro-optic device.

In other embodiments of this invention, devices according to embodiments of this invention are manufactured according to methods of this invention.

### BRIEF DESCRIPTION OF THE DRAWINGS

The invention can be better understood by reading the following detailed description with reference to the accompanying figures in which:

FIG. 1 is a schematic illustration of an electro-optic device according to an embodiment of the current invention;

FIG. 2 shows electroluminescence spectra of PLED devices with four different compositions according to embodiments of the current invention (the photoluminescence spectra for the 2 wt % device is shown by the dashed line and the CIE color coordinate of EL emission are shown in the inset for these four devices);

FIG. 3(a) shows the decay of PL with time and FIG. 3(b) shows the exciton lifetime at the selected wavelength for PFO, MEH-PPV and PFO:MEH-PPV films;

FIG. 4 shows characteristics of external efficiency and power efficiency as functions of current density for four example PLEDs according to an embodiment of the current invention;

FIG. 5 contains Table I listing the performance of devices with different compositions according to the current invention;

FIG. 6 contains Table II comparing an embodiment of the current invention to conventional devices;

FIG. 7 shows Luminance efficiencies of three groups of devices to illustrate some concepts of the current invention;

FIG. 8(a) shows Voc and power efficiency of PLEDs based oil Al according to embodiments of the current invention;

FIG. 8(b) shows the same device characteristics as in FIG. 6(a) but with Ag electrodes; and

FIGS. 9(a) and 9(b) show the I-V curves of the device based on Al and Ag electrodes, respectively.

### DETAILED DESCRIPTION

In describing embodiments of the present invention, specific terminology is employed for the sake of clarity. However, the invention is not intended to be limited to the specific terminology so selected. It is to be understood that each specific element includes all technical equivalents which operate in a similar manner to accomplish a similar purpose.

According to an embodiment of this invention, a general method is provided to significantly increase the efficiency of polymer light emitting diodes (PLEDs) by controlling the charges, via material and device engineering, in the light-emitting polymer (LEP) layer. By blending high bandgap and low bandgap polymers in proper ratios, we are able to introduce charge traps in the LEP layer according to an embodiment of this invention. In addition, by introducing an electron injection/hole blocking layer, we are able to enhance the minority carrier (electrons) injection and block holes. Efficient and balanced charge injection as well as charge confinement can be attained simultaneously according to embodiments of this invention. As a result, very highly efficient devices have been achieved according to this embodiment of the invention. As an example of this approach, we have blended 0.5%-2% of Poly[2-methoxy-5-(2′-ethyl-hexyloxy)-1,4-phenylene vinylene] (MEH-PPV) with poly(9,9-dioctylfluorene) (PFO) as an active polymer for PLEDs. A Cs₂CO₃ charge injection and hole block layer is used at the cathode interface. The device's emission covers colors from white to yellow, depending on the blend ratios, with the highest peak efficiency obtained of 16 lumen/watt (lm/W) in these examples. To our knowledge, this is the highest reported efficiency for white emission fluorescence PLEDs. The same approach of material engineering can also apply to the following systems: (a) polymer host with organic molecule dopants, the molecules can be either a singlet (fluorescence) dopant of a triplet (phosphorescence) dopant, as long as they satisfy the charge trapping and energy transfer requirement; (b) the dopant molecules can be dendrimer with the same condition illustrated in (a); and (c) a co-polymer system with a higher energy and lower energy bandgap polymers as the constituent elements of the co-polymer. The interfacial layer, in addition to Cs₂CO₃, includes but is not limited to Ca(acac)₂, Ba(acac)₂, LiF and other metal oxide, metal-complexes from the first two columns of the periodic table.

Examples of polymer hosts include:

PPP type: Poly(para-phenolyene)
PPV type: Poly(phenylene vinylene)
PF type: Polyfluorene
PT type: Polythiophene
PVK type: poly-9-vinylcarbazole
Poly-TPD type: Poly(N,N′-bis(4-butylphenyl)-N,N′-bis(phenyl)benzidine),
and copolymers and derivatives of these polymers.

Examples of dopants include:
Tris(2-phenylpyridine) iridium (III) (Ir(ppy)3);
10-(2-Benzothiazolyl)-2,3,6,7-tetrahydro-1,1,7,7,-tetramethyl-1H,5H,11H-[1]benzopyrano[6,7,8-ij]quinolizin-1-one (C545T);
Tris(benzoylacetonato)-mono(1,10-phenanthroline)curopium (III) (Eu-BA);
2,3,7,8,12,13,17,18-Octaethyl-21H,23H-porphine platinum (II) (MPOEP);
N,N′-Dimethylquinacridone (DMQA);
4-(Dicyanomethylene)-2-methyl-6-(p-dimethylaminostyryl)-4H-pyran (DCM);
[2-(2-propyl)-6-[2-(2,3,6,7-tetrahydro-2,2,7,7-tetramethyl-1H,5H-benzo[ij]quinolizin-9-yl)ethenyl]-4H-pyran (DCJTI);
4,4′-Bis(2,2-diphenylethene-1-yl)biphenyl (DPVBi);
5,6,11,12-tetraphenylnaphthacene (Rubrene);
4-(dicyanomethylene)-2-tert-butyl-6-(1,1,7,7-teramethyljulolidyl-9-enyl)-4H-pyran (DCJTB);
Bis(3-(2-(2-pyridyl)benzothenoyl)mono-acetylacetonate iridium III ((BTP)2Ir(ACA C));
   and derivatives of these molecular dopants.

The amount of dopant used can vary from 0.25 wt % up to 8 wt %. For singlet dopants, the amount used is typically around 1 wt %. For triplet dopants, the amount used is typically around 6 wt %.

Examples of Eu based phosphorescent materials include:
Tris[bis(4-((2-ethoxy)-2-ethoxy)ethoxy)benzoyl)methane]mono(5-aminophenathroline)europium (III)
Tris(benzoylacetonato)-mono(phenanthroline)europium (III)

### Common Name: Eu-BA

Tris(biphenylmethane) mono(phenanthroline)europium (III)

### Common Name: Eu-BDBBM

Tris(dibenzoylmethane) mono(phenanthroline)europium (III)

### Common Name: Eu-DBM

Tris(dibenzoylmethane) mono(4,7-dimethylphenathroline) europium (III)

### Common Name: Eu-DBM-DM

Tris(dibenzoylmethane) mono(4,7-diphenylphenathroline) europium (III)

### Common Name: Eu-DBM-DP

Tris(dibenzoylmethane) mono(5-aminophenanthroline) europium (III)

### Common Name: Eu-DBM-NH

Tris(dibenzoylmethane) mono(5-aminophenanthroline) europium (III)

### Common Name: Eu-DBM-NH

Tris(dinaphthoylmethane) mono(phenanthroline)europium (III)

### Common Name: Eu-DNM

Examples of Ir based phosphorescent materials include
Bis(3,5-Difluoro-2-(2-pyridyl)phenyl-(2-carboxypyridyl) iridium III

### Common Name: F(Ir)pic

Bis(dibenzo[f,h]quinoxaline)(acetylacetonate) Iridium (III)
   Common Name: Ir(DBQ)2(acac)
Bis(3-(2-(2-pyridyl)benzothenoyl)mono-acetylacetonate iridium III

### Common Name: (BTP)2Ir(ACAC)

Tris(1-phenylisoquinoline) iridium (III)

### Common Name: Ir(piq)3

Tris[2-(2-pyridinyl)phenyl-C,N]-iridium; Tris(2-phenylpyridine) iridium (III)

### Common Name: Ir(ppy)3

iridium (III) tris(2-(4-tolyl)pyridinato-N,C2′

### Common Name: Ir(tpy)3

Examples of Pt based phosphorescent materials include:
5,15-bis[4-(4,4-dimethyl-2,6-dioxacyclohexyl)phenyl]-2,8,12,18-tetrahexyl-3,7,13,17-tetramethylporphyrin platinum(II)
5,15-bis(2,6-dimethoxyphenyl)-2,8,12,18-tetrahexyl-3,7,13,17-tetramethylporphyrinato platinum(II)
3,5-di-tert-butylphenyl substituents [5,15-bis(3,5-di-t-butylphenyl)-2,8,12,18-tetrahexyl-3,7,13,17-tetramethylporphyrin platinum(II)

Examples of Er based phosphorescent materials include Er-DBM and Er-DBM-DP.

Cu or Ru based phosphorescent materials may also be used.

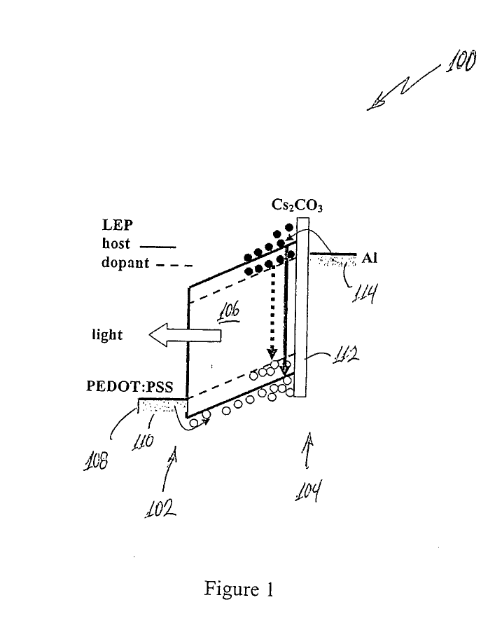

There are several benefits that can be achieved in using a polymer blend according to some embodiments of this invention, such as: (1) Low bandgap LEP behaves as a dopant for energy transfer from the higher bandgap LEP; (2) Low bandgap LEP behaves as charge trap sites to trap (and confine) the injected charges, which is particularly important in the low voltage regime; and (3) The trapped electrons at low bandgap LEP will eventually help the injection of holes and lead to a self-balanced charge injection. When this LEP blend system combines with an electron injection and hole blocking layer of Ca(acac)₂ (Qianfei Xu, Jianyong Ouyang & Yang Yang, Appl. Phys. Lett. 2003 83, 4695) or Cs₂CO₃ (Yoichi Osato & Hidemasa Mizutani, 2004, SID's 04 DIGEST) at the cathode interface, holes are blocked within the LEP layer as well. As a result, both electrons and holes are effectively confined in the LEP rather than being extracted directly by electrodes. As a result, efficient recombination occurs due to the overlap distribution of electrons and holes (through formation of excitons). All of these factors can help to increase the efficiency of PLED devices. The schematic electronic profile for the structure is shown in FIG. 1.

FIG. 1 is a schematic illustration of an electro-optic device 100 according to an embodiment of the current invention. The electro-optic device 100 has a first electrode 102 and a second electrode 104 spaced apart from the first electrode 102. An active polymer layer 106 is disposed between the first electrode 102 and the second electrode 104. In this example, the electro-optic device 100 is a PLED. In this embodiment, the first electrode 102 has an ITO layer 108 and a PEDOT:PSS layer 110. The second electrode 104 in this embodiment performs both electron injection and hole blocking. In this example, the electrode 104 has a layer 112 of Cs₂CO₃ formed on a layer of metal 114. Al and Ag have been found to be suitable materials for the layer of metal 114. The layer 112 may be formed by various methods according to the current invention. For example, spin coating Cs₂CO₃ onto a layer of Al has been found to be suitable according to embodiments of the current invention, as will be described in more detail below with respect to specific examples. However, the concepts of the current invention are not limited to the specific embodiments described. In addition, thermal deposition of Cs₂CO₃ onto the layer of metal 114 has also been found to be suitable for Al and Ag metal layers, as will be described in more detail below for particular examples. Again, the concepts of this invention are not limited to these specific examples.

Previously, the efficiency of green PLEDs were improved, where poly(9,9-dioctylfluorene) (PFO) was used as the host polymer, 5% poly(9,9-dioctylfluorene-co-benzothiadiazole) (F8BT) was used as dopant and Ca(acac)₂ was used as the nano-scale interfacial layer (Qianfei Xu, Jianyong Ouyang & Yang Yang, Appl. Phys. Lett. 2003 83, 4695). The highest efficiency of such a device is about 28 cd/A, which is more than four times that of a regular device with a Ca cathode. In order to verify this method on other material systems, we choose orange polymer Poly[2-methoxy-5-(2′-ethyl-hexyloxy)-1,4-phenylene vinylene] (MEH-PPV) as the dopant, and Cs₂CO₃ to replace Ca(acac)₂. One interesting property of the MEH-PPV:PFO system is that the white light emission can be realized by incomplete transfer of energy from PFO to MEH-PPV at low MEH-PPV concentration. Cs₂CO₃ has been shown to be a better electron injection material than LiF. (See Yoichi Osato & Hidemasa Mizutani, 2004, SID's 04 DIGEST.) This is consistent with our observation that the green PLED device based on the PFO:F8BT system has a lower working voltage using a Cs₂CO₃ cathode than a device using Ca(acac)₂ cathode (operation voltage at 25 mA/cm² decreases from 5.3V to 4V using the same parameters for devices). This suggests that improved charge balance and conductivity of interfacial layer are obtained using Cs₂CO₃.

### EXAMPLE 1

Four types of devices with the structure of ITO/poly(ethylene dioxy thiophene):polystyrene sulfonate (PEDOT:PSS)/PFO:MEH-PPV/Cs₂CO₃/Al were fabricated. In order to solution process the electron injection and hole blocking layer, Cs₂CO₃ was dissolved in 2-ethoxyethonal to form a dilute solution. The three layers of films PEDOT:PSS, PFO:MEH-PPV and Cs₂CO₃ were formed by spin-coating one layer after another. The thickness of the polymer blend layer is between 80 to 100 nm. The color of EL can be modulated from yellow to white by changing the concentration of MEH-PPV from 2 wt % to wt 0.25 wt %.

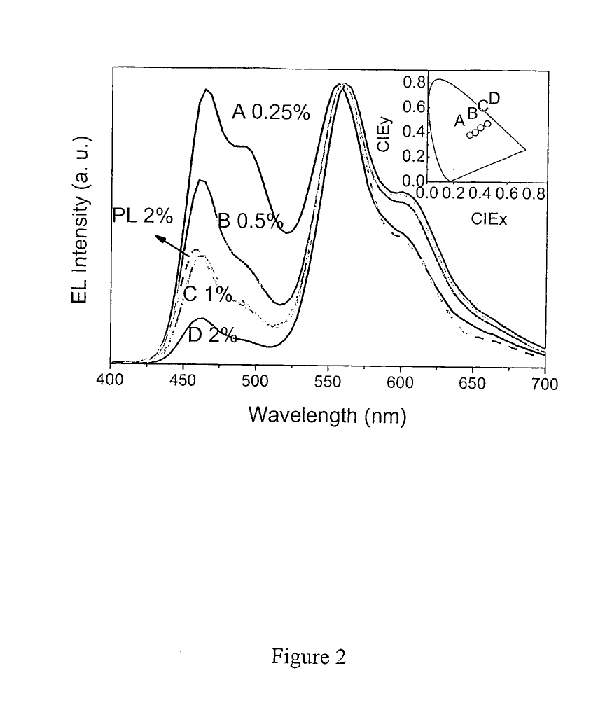

FIG. 2 shows the normalized EL spectra of devices at 25 mA/cm² with four different concentrations. All EL spectra show emission from both MEH-PPV and PFO. With the increasing concentration of MEH-PPV in PFO, the relative emission intensity from PFO decreases due to the energy transfer from PFO to MEH-PPV. Yellow emission from MEH-PPV is observed from the sample with high MEH-PPV concentration of 2 wt %, and white emission color is obtained at lower MEH-PPV concentration devices. The CIE color coordinates of the emission are shown in the inset of FIG. 2. The white emission PLED device with 0.25 wt % MEH-PPV has the CIE coordinate of (0.32, 0.38). The energy transfer process from PFO to MEH-PPV is proved by the decreasing emission from PFO with the increasing MEH-PPV concentration, and also illustrated by comparing PL and EL spectra of the polymer films and devices, shown in FIG. 2 for the 2 wt % sample. In both PL and EL two peaks appear which correspond to the emission of blue PFO and MEH-PPV. Significant differences in the peak intensities (as well as the ratios) between the PL spectrum and EL spectrum were observed, which is common in blended material systems. This is due to the fact that the PL emission process, an instant excitation and recombination process, does not involve the charge transport process (Mitsunori Suzuki, Takuya Hatakeyama, Shizuo Tokito and Fumio Sato. 2004, 1, 115). Hence the possibility that the charges (photon excited or electrical injected) are trapped by low band-gap MEH-PPV is less in the PL emission than the EL emission process.

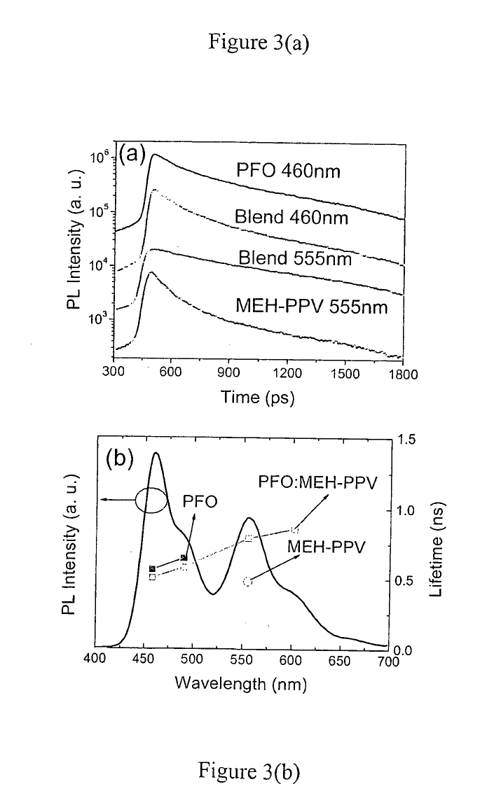

Direct evidence of the energy transfer process comes from the lifetime measurement by the picosecond time-resolved photoluminescence spectra, shown in FIG. 3. For excitons in PFO, the lifetime decreases from 0.57 to 0.48 ns when MEH-PPV is introduced as the dopant. This is due to the energy transfer process between PFO and MEH-PPV. On the other hand, for excitons in MEH-PPV, the lifetime increases from 0.48 to 0.78 ns. The actual reason is unknown, but it is likely that MEH-PPV has been significantly diluted, and the PL is originated from the energy transferred from PFO. This observation is important in light of improving device performance, and we will provide a more detailed discussion below.

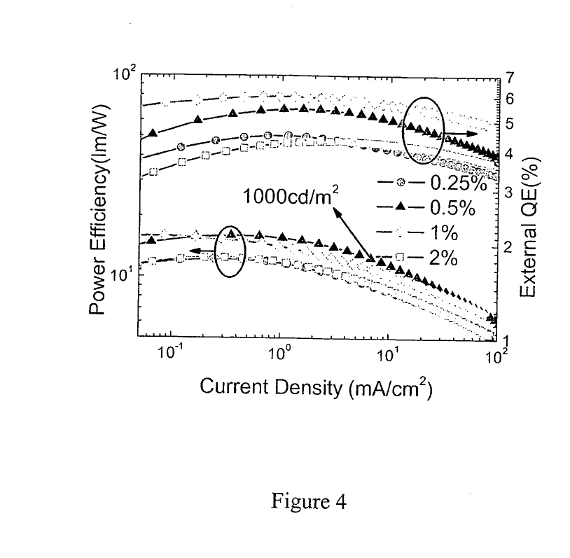

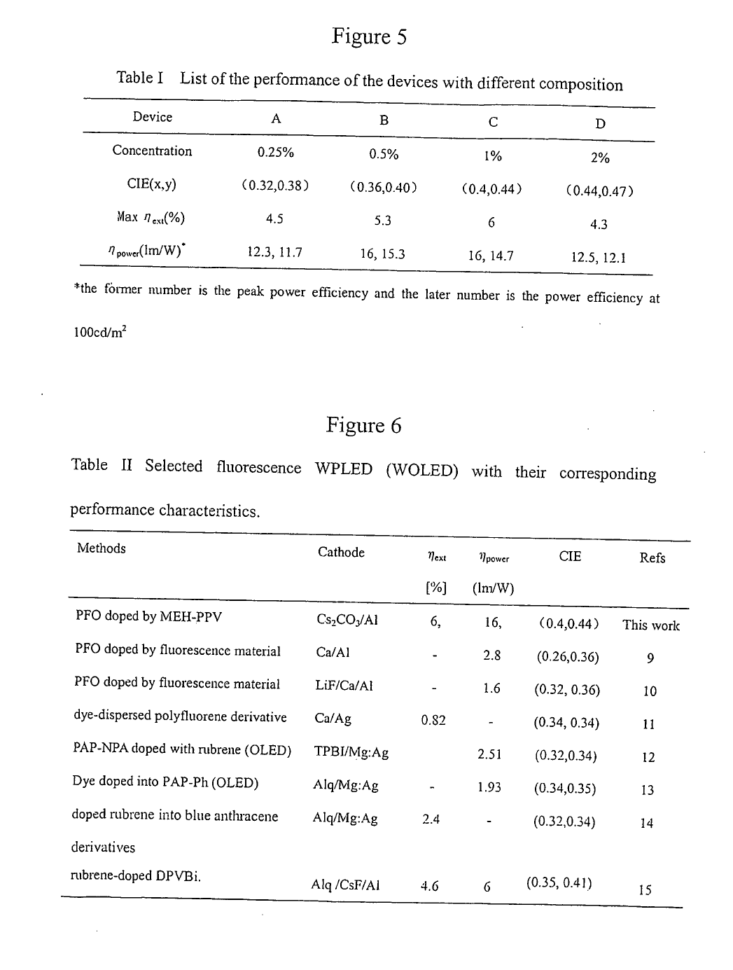

Our devices show very good performance. The leakage current before light turn-on is low (˜10⁻⁵ mA/cm²), which is ideal for large area illumination applications. Light emission is observed at low applied external voltage of 2.3 V. Our single emission layer structure assures low operating voltage: the emitting intensity reaches 3000 cd/m² and 10000 cd/m² at voltages of 4.3V and 5.4 V respectively, for the 0.5 wt % device. These are the lowest operation voltages reported for a white PLED. This device can even compare to the brightest reported phosphorescence white OLED at such high luminance (Brian W. D'Andrade, Russell J. Holmes, and Stephen R. Forrest. Adv. Mater. 2004, 16, 624). This high performance device is attributed to the excellent balance of electrons and holes, and charge confinement. In addition, the polymer system has a high PL efficiency. The power efficiency versus current density of the four devices is shown in FIG. 4. The forward external quantum efficiency ( [symbol] ₑᵥ) is calculated according to the luminous efficiency and EL spectra at 25 mA/m², which is also shown in FIG. 4. The maximum [symbol] ₑₓ are 6% for the white device (device C) at 110 cd/m² and 4.3% for the yellow device (device D) at 300 cd/m². The peak power efficiencies for the white and yellow devices are 16 lm/W (device B,C) and 12.5 lm/W (device D), respectively, at low current density. The power efficiency at 100 cd/m² is still as high as 15.3 lm/W (device B) and 12.1 lm/W (device D) for the white and yellow devices, respectively. The performance parameters of all of the four devices are provided in Table 1 (attached as FIG. 5). To our knowledge, this is significantly higher than the previously reported power efficiency for the fluorescent white PLED. A comparison between the performance of our device and those previously reported is listed in Table II (attached as FIG. 6). Here we would like to emphasis the high internal QE of our devices. Assuming the output coupling efficiency of 20% (Chihaya Adachi, Marc A. Baldo, Mark E. Thompson, and Stephen R. Forrest. J. Appl. Phys. 2001, 90, 5046), the internal QE is estimated to be 30%. For the system of PFO:F8BT, the internal QE is estimated to be 40%. Both numbers exceed the limit of 25% for the fluorescence emission according to the statistical result of the electron spin. Our results supports that the triplet-singlet formation cross-section ratio can be lower than 3 in the long-chain polymer (J. S. Wilson, A. S. Dhoot, A. J. A. B. Seeley, M. S. Khan, A. Kohler & R. H. Friend, Nature (London). 2001 413, 828; M. Wohlgenannt, X. M. Jiang, Z. V. Vardeny & R. A. J. Janssen, Phys. Rev. Lett. 2002, 88, 197401).

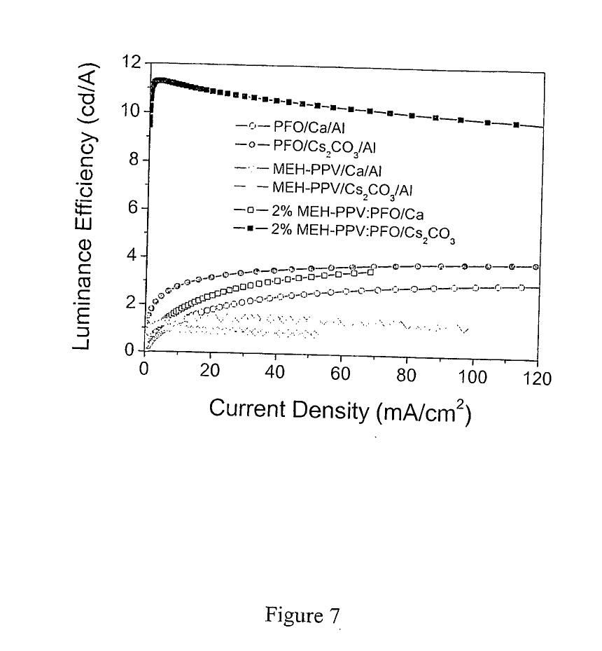

The improvement in performance seems to result from the combination of two factors: self-balanced efficient charge injection and charge confinement. Minor increase of luminous efficiency can be obtained if only one condition is satisfied. This is illustrated by the comparison of luminous efficiencies for three groups of devices, as shown by FIG. 7. For devices with the same device stricture, luminous efficiency reflects the degree of charge balance giving the same EL spectra. The three groups of devices are: MEH-PPV, PFO, and 2 wt % MEH-PPV:PFO devices, using Ca and Cs₂CO₃ as cathodes for each group. The reason why we chose a high percentage MEH-PPV sample for comparison is because the EL emission of this sample composed mainly from MEH-PPV, and the contribution for the improved efficiency from PFO emission is excluded. For the MEH-PPV and PFO devices with two different cathodes, the luminous efficiencies of devices with Cs₂CO₃ cathodes increase to 1.4 and 1.3 times over the devices with Ca cathodes. For the same Ca cathode devices, the doped MEH-PPV:PFO device has an efficiency of 3.5 times over the MEH-PPV device, which should partially account for the increased PL efficiency of polymer film. When both dopant and a hole blocking layer are used, the efficiency is improved to 11.2 cd/A, which is almost 11 times of the MEH-PPV/Ca device and more than three times that of the MEH-PPV:PFO/Ca device.

A general method to boost the efficiency of PLED devices is provided according to embodiments of the current invention. In this structure, efficient and self-balanced charge injection and charge confinement are achieved simultaneously. WPLEDs can be realized by the incomplete transfer of energy from PFO to MEH-PPV, and the color is modulated from yellow to white by changing the concentration of MEH-PPV. The device shows very good performance, and the highest power efficiency of 16 lm/W according to one example is obtained for our fluorescent WPLED.

### EXPERIMENTS

The PLEDs were fabricated on a pre-cleaned indium-tin-oxide (ITO) substrate with a sheet resistance of 20 Ω/sq. A buffer layer of 30 nm poly(ethylene dioxy thiophene)/polystyrene sulfonate (PEDOT:PSS) was used as a hole injection layer at the anode interface between ITO and the emission polymer. Spin-coated polymer films were baked at 70° C. to remove the solvent. A Cs₂CO₃ layer was spin-coated on polymer films. The devices were formed by the evaporation of cathode metal Al.

The current-voltage and light-voltage curves were recorded with a Keithley 2400 source-measure unit and a calibrated silicon photodiode. The luminance was further measured by a Photo Research PR650 spectra photon-meter. The Commission International del'Eclarirage (CIE) (1931) coordinates were used to describe the color of the devices, including hue and saturation. The PL and EL spectra of the polymer doped with different weight ratios were studied with a Jobin Yvon Spex Fluorolog-3 double-grating spectrofluorimeter and a Photo Research PR650 spectrophotometer, respectively.

For TRPL measurements, the PL was excited by frequency-doubled (λ=375 nm) laser pulses from a Ti:Sapphire mode-locked femtosecond laser and the time-correlated signals were analyzed by a two-dimensional (2D) synchronous streak camera with an overall resolution of better than 15 ps.

### EXAMPLE 2

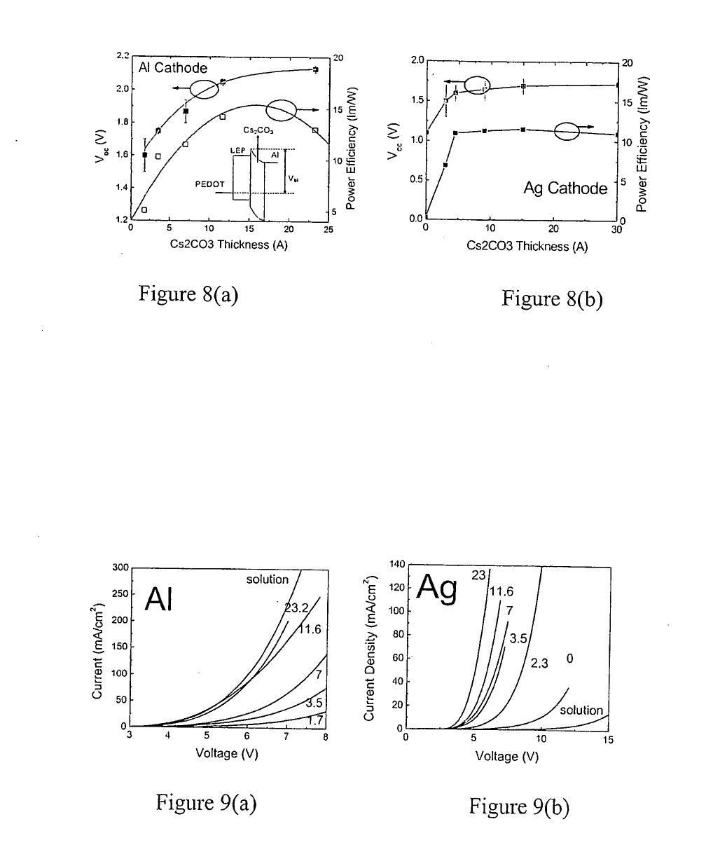

Solution processed Cs₂CO₃ as an electron injection layer provides a very convenient method to fabricate ultra-high performance PLED devices. (See Example 1 above.) However electron injection materials such as Cs₂CO₃ are not limited to only solution processing as described in Example 1. Thermally evaporated Cs₂CO₃ combined with an Al cathode can also play the same role of facilitating the injection of electrons, as shown in FIG. 8, thereby achieving high performance.

FIG. 8 (a) shows the power efficiency of the white emission PLED devices with different thicknesses of Cs₂CO₃ layer. Here the device structure remains as ITO/PEDOT:PSS/LEP (0.5% MEH-PPV doped in PFO)/Cs₂CO₃/AI, however the Cs₂CO₃ layer is obtained by a thermal evaporation process, a process commonly used in the fabrication of PLEDs and OLEDs. As we can see from FIG. 8(a), the same maximum power efficiency of 16 lm/W as in case of solution processed Cs₂CO₃ can be obtained by optimizing the thickness of Cs₂CO₃ layer.

Intensive study has been done to determine the mechanism of solution processed and thermally evaporated Cs₂CO₃ in improving the efficiency of PLED devices. In order to test if Al is required to be the metal cathode to improve the efficiency of the device, other metal cathodes were used. In particular, Ag was selected for this application because the work function of Ag is similar to that of Al, but it has much less chemical reactivity.

FIG. 9 shows the current-voltage plots for the devices using thermally evaporated Cs₂CO₃ of varying thicknesses as well as the solution processed Cs₂CO₃ device, using Al or Ag as cathodes. As one can see from the figures, for the thermally evaporated Cs₂CO₃ devices, the current increases with increasing Cs₂CO₃ thickness, for both Al and Ag cathode devices, which demonstrates that a Cs₂CO₃ nano-layer facilitates the injection of electrons. No saturation of current with Cs₂CO₃ thickness is observed in our experiment range of Cs₂CO₃ thickness, in contrast to LiF. Also, devices using Al cathodes have higher current density than those using Ag cathodes, which means that the Al/Cs₂CO₃ cathode has even lower work function. A more obvious difference between the devices using Al and Ag cathodes is observed for the solution processed Cs₂CO₃: for Al cathode devices, the current is comparable to that of thermally evaporated Cs₂CO₃ devices with same thickness; while for Ag cathode devices, the current is as small as the device with a polymer/Al configuration, which means solution processed Cs₂CO₃ does not play any role to increase the injection of electrons from Ag.

In order to find out the reason for increased electron injection from Cs₂CO₃, the work function of the Cs₂CO₃/Al cathode is measured using photovoltaic measurement. In this measurement, the PLED devices are treated as photovoltaic devices and the photo currents are measured when the devices are subjected to 1.5 M simulated sun light. The open circuit voltage (V_{oc}) obtained from this measurement is correlated, if not exactly the same (because of dipole formation at the interface), to built-in potential in the PLED devices, which is defined as the difference in work function of anode and cathode. FIG. 8 shows the relationship of V_{oc} with the thickness of Cs₂CO₃ for both Al and Ag cathodes. As one can see from the figure, V_{oc} increases linearly with Cs₂CO₃ thickness for devices with Al or Ag cathodes when Cs₂CO₃ is thin, and saturates when Cs₂CO₃ is thick enough. Since the parameters of these devices are the same except for the thickness of Cs₂CO₃ (dipole configuration at the interface is also the same for all devices), the higher V_{oc} indicates essentially the lowering of the work function of the CsCO₃/Al cathode. The energy diagram of the device is shown in the inset of FIG. 8(a). This is direct evidence that evaporated Cs₂CO₃ can reduce the work function of Al and Ag cathodes. It has been reported that the low work function of thermally evaporated Cs₂CO₃ is its intrinsic bulk property is (T. R. Briere and A. H. Sommer, J. Appl. Phys. 48, 3547 (1977); A. H. Sommer, J. Appl. Phys. 51, 1254 (1979)). Then the evolution of work function with Cs₂CO₃ thickness demonstrates how the Cs₂CO₃ film forms, which agrees with the former AFM result. It is noted that the saturated V_{oc} for devices with Ag as the cathode is lower than that of devices with Al cathodes, which means even lower work function can be realized in Cs₂CO₃/Al cathodes. This agrees with the I-V results, shown in FIG. 9, that currents in devices with Al cathodes are higher than that with Ag cathodes at the same voltage and for the same Cs₂CO₃ layer thickness. It is expected that the reaction of cesium oxide and Al would produce a low work function metal oxide Al—O—Cs, which has been confirmed by the XPS measurement.

Both solution processed and thermally evaporated Cs₂CO₃ films can help the injection of electrons from Al cathodes according to embodiments of the current invention. However the mechanisms are different for these two methods. For the solution processed Cs₂CO₃, the reaction of hot Al with Cs₂CO₃ results in the product of Cs—O—Al oxide, which has a low work function. For thermally evaporated Cs₂CO₃, Cs₂CO₃ decomposes into CsxOy, which also has a low work function. As a result, the devices with the thermally deposited Cs₂CO₃ are relatively independent on the cathode metal used. The reaction of CsxOy with Al can further reduce the work function. Thermally deposited Cs₂CO₃ can also be applied to other alkali metals and Alkaline Earths metal complexes.

The current invention was described with reference to particular embodiments and examples. However, this invention is not limited to only the embodiments and examples described. One of ordinary skill in the art should recognize, based on the teachings herein, that numerous modifications and substitutions can be made without departing from the scope of the invention which is defined by the claims.

We claim:

1. An electro-optic device, comprising:
a first electrode;
a second electrode spaced apart from said first electrode; and
an active polymer layer disposed between said first electrode and said second electrode,
wherein said active polymer layer is a polymer blend comprising a high band gap material and a low band gap material.

2. An electro-optic device according to claim 1, wherein said active polymer layer is a blend of MEH-PPV with PFO.

3. An electro-optic device according to claim 2, wherein said polymer blend comprises at least about 0.25 wt % to about 2 wt % of MEH-PV.

4. An electro-optic device according to claim 1, wherein said polymer blend comprises a combination of high and low bandgap conjugated polymers in a ratio ranging from about 0.1 wt % to 40 wt % for said low bandgap material.

5. An electro-optic device according to claim 4, wherein said low bandgap material is selected from organic molecules.

6. An electro-optic device according to claim 4, wherein said low bandgap material is selected from molecules having a triplet energy level

7. An electro-optic device according to claim 4, wherein said low bandgap material is selected from organic dendrimers.

8. An electro-optic device according to claim 1, wherein said low bandgap material is selected from dendrimers having a triplet energy level.

9. An electro-optic device according to claim 1, wherein said low bandgap material comprises a plurality of dopants each selected from the group consisting of low bandgap polymers, small molecules, and dendrimers, having singlet and triplet energy levels at a ratio determined according to optimizing device performance.

10. An electro-optic device according to claim 1, wherein said first electrode is an anode comprising a PEDOT:PSS hole injection layer deposited on an ITO substrate.

11. An electro-optic device according to claim 1, wherein said second electrode is a cathode that is constricted to provide both electron injection and hole blocking.

12. An electro-optic device according to claim 11, wherein said cathode comprises a layer of Cs₂CO₃.

13. An electro-optic device according to claim 12, wherein said cathode further comprises a layer of A [symbol] formed on said layer of Cs₂CO₃.

14. An electro-optic device according to claim 13, wherein said first electrode is an anode comprising a PEDOT:PSS hole injection layer deposited on an ITO substrate.

15. An electro-optic device, comprising:
an anode;
a cathode spaced apart from said anode; and
an active polymer layer disposed between said cathode and said anode,
wherein said cathode is constructed to provide both electron injection and hole blocking.

16. An electro-optic device according to claim 15, wherein said cathode comprises a layer of Cs₂CO₃.

17. An electro-optic device according to claim 16, wherein said cathode further comprises a layer of A [symbol] formed on said layer of Cs₂CO₃.

18. An electro-optic device according to claim 15, wherein said anode comprises a PEDOT:PSS hole injection layer deposited on an ITO layer.

19. An electro-optic device according to claim 17, wherein said anode comprises a PEDOT:PSS hole injection layer deposited on an ITO layer.

20. A method of manufacturing an electro-optic device, comprising:
providing a substrate;
forming an active polymer layer on said substrate;
forming a layer of Cs₂CO₃ on said active polymer layer; and
depositing a layer of metal onto said layer of Cs₂CO₃;
wherein said layer of Cs₂CO₃ on said active polymer layer provides electron injection and hole blocking for said electro-optic device.

21. A method of manufacturing an electro-optic device according to claim 20, wherein said layer of Cs₂CO₃ is formed by spin coating onto said active polymer layer, and
wherein said layer of metal deposited onto said layer of Cs₂CO₃ consists essentially of Al.

22. A method of manufacturing an electro-optic device according to claim 20, wherein said layer of Cs₂CO₃ is formed by thermal deposition of Cs₂CO₃ onto said active polymer layer.

23. A method of manufacturing an electro-optic device according to claim 22, wherein said layer of metal formed on said layer of Cs₂CO₃ consists essentially of a metal selected from the group consisting of alkali metals and alkaline earth metal complexes.

24. A method of manufacturing an electro-optic device according to claim 22, wherein said layer of metal formed on said layer of Cs₂CO₃ consists essentially of a metal selected from the group consisting A [symbol] , Ag and any mixtures thereof.

25. A method of manufacturing an electro-optic device according to claim 20, wherein said substrate comprises a layer of ITO.

26. A method of manufacturing an electro-optic device according to claim 25, wherein said substrate further comprises a layer of PEDOT:PSS formed on said layer of ITO,
wherein said layer of ITO and said layer of PEDOT:PSS together provide an anode having a hole injection layer.

27. An electro-optic device manufactured according to the method of claim 20.

28. An electro-optic device manufactured according to the method of claim 21.

29. An electro-optic device manufactured according to the method of claim 22.

30. An electro-optic device manufactured according to the method of claim 23.

31. All electro-optic device manufactured according to the method of claim 24.

32. An electro-optic device manufactured according to the method of claim 25.

33. An electro-optic device manufactured according to the method of claim 26.
